(19) United States
(12) Patent Application Publication
(10) Pub. No.: US 2006/0021566 A1
(43) Pub. Date: Feb. 2, 2006

(54) Method and apparatus for forming long single crystals with good uniformity

(75) Inventor: Chung-Wen Lan, Sindian City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: National Taiwan University, Taipei City (TW)

(21) Appl. No.: 10/937,124

(22) Filed: Sep. 9, 2004

(30) Foreign Application Priority Data
Aug. 2, 2004 (TW) 93123136

(51) Int. Cl. C30B 11/00

(52) U.S. Cl. 117/200; 117/900

(57) ABSTRACT

A crystal growth apparatus and a method for forming a long single crystal with good uniformity are provided. The crystal growth apparatus includes a first crucible, a first heater configured around the first crucible, a second crucible configured inside the first crucible, a pulling system for pulling a crystal, so as to grow the crystal in a crystal growth zone and a moving system for forming a relative movement between the first crucible and the second crucible.

### FIELD OF THE INVENTION

The present invention is related to a crystal growth apparatus and a method for growing crystals, in particular, to a crystal growth apparatus adopting Czochralski method for growing single crystals.

### BACKGROUND OF THE INVENTION

Demands for the photo-crystals are increasing as the optical and photoelectrical technologies developing. The noble crystals, such as the lithium niobate (LN, LiNbO₃) crystal, the lithium tantalum (LT, LiTaO₃) crystal and the sapphire, are necessarily applied for the relevant technologies for the optical communication, the acousto-optic, the harmonic laser, the optical storage and the light-emitting techniques.

The Czochralski method, i.e. a pulling method, is commonly adopted in the conventional processes for growing the single photo-crystals, such as LN, LT and the sapphire. The steps involved in the Czochralski method, which relates to a kind of batch production for growing the crystals, are illustrated as follows.

First, the primary material is fed into the crucible in the crystal growth apparatus, and then heated by the heater therein. While the temperature in the crucible is increased to the melting point, the primary material is melted to form a melt. Then, the crystal seed is added into the melt in the crucible when a stable surrounding condition is maintained therein. The crystal seed is pulled off the melt, and the needed crystal is formed on the crystal seed, accordingly. As soon as the crystal seed is pulled off the melt and the grown crystal is formed, the surrounding temperature would be gradually decreased. By controlling the pulling velocity and the surrounding temperature in the crystal growth process, the crystal could be stably grown and the diameter of the grown crystal could be controlled. Therefore, a crystal bar having a predetermined diameter and length is formed and obtained therefrom.

Since the Czochralski method relates to a batch production process, the composition of the grown crystal is hence not easily controlled in each batch. Furthermore, the length of the grown crystal is always limited and the yield of the crystal bar is difficult to be improved as a result. Therefore, it really needs great efforts on the continuous growth process for improving the yield to reduce the production cost thereof.

Recently, the conventional Czochralski method is improved and a double-crucible system for pulling and growing the crystal is developed. The double-crucible system realized the continuous growth process, and a LN single crystal with a large size and having a chemically stoichiometric L/N ratio of 1:1 is obtained therefrom. Moreover, the LT single crystal is also attempted to be grown in such a system.

Please refer to FIG. 1, which schematically illustrates the double-crucible system according to the prior art. The double-crucible system 1′ includes an automatic powder supplier 10′, a pulling system 20′, an inner crucible 30′ and an outer crucible 40′. The primary material 15′, which relates to a plurality of powders, is automatically fed into the outer crucible 40′, and then heated and melted therein. The melt thereof is guided and flows into the inner crucible 30′. Finally, the crystal bar 50′ is gradually formed by the pulling system 20′ pulling.

The double-crucible system 1′ costs a lot because of the complicated and expensive automatic power supplier 10′ therein. Additionally, the double-crucible system 1′ is separated, which could not be incorporated into the conventional crystal growth apparatus. Therefore, it has less potential for practicable and popularized applications.

In order to improve the yield, not only the development of the continuous process, but also the increment of the length of the grown crystal must be considered. It is quite difficult to improve the length of the grown crystal and maintain the composition uniformity thereof due to the limitations of the size of the crucible and the power of the heater in the conventional crystal growth apparatus, which is related to utilize the conventional Czochralski method. Nowadays, it is preferred to use a large inner crucible for growing a long single crystal. However, such a measure has the following drawbacks, which are necessary to be overcome.

First, a higher heating power of the heater is necessary while a large inner crucible is used in the crystal growth apparatus. This may result in a more consumption for energy. Second, the natural heat convection in the crucible and the surroundings would be substantially enhanced if a larger crucible is used. This may result in a large gradient of temperature in the surroundings. The grown crystal would be of inferior quality accordingly. Finally, the cost of the large crucible is extremely high.

For overcoming the above drawbacks in the crystal growth process and apparatus according to the prior art, the present invention provides an improved method for growing the crystal and an improved crystal growth apparatus accordingly. The structure and arrangements thereof are more simplified than those in the conventional ones. The solid primary material is fed and melted through a zone-melting method. Hence the melt is able to be prepared in a small inner crucible, which would reduce the heat convection at the growing interface therein. The thermal stability in the melting zone is improved and the quality of the grown crystal would be excellent as a result. Furthermore, a single crystal having a uniform composition and a large length would be grown and formed through a continuous feeding of the solid primary material.

### SUMMARY OF THE INVENTION

In accordance with a first aspect of the present invention, a crystal growth apparatus is provided. The crystal growth apparatus includes a first crucible, a first heater configured around the first crucible, a second crucible configured inside the first crucible, a pulling system for pulling a crystal, so as to grow the crystal in a crystal growth zone and a moving system for forming a relative movement between the first crucible and the second crucible.

Preferably, the crystal growth apparatus further includes a thermal shield for providing a thermal insulation zone for the crystal growth zone.

Preferably, the second crucible further has at least a hole on a wall thereof.

Preferably, the crystal growth apparatus further includes a second heater configured around the crystal growth zone.

Preferably, the second crucible is configured inside the first crucible by a fixed support.

Preferably, the second crucible further has at least a hole on a wall thereof.

Preferably, the crystal growth apparatus further includes a second heater configured around the crystal growth zone.

In accordance with a second aspect of the present invention, a method for forming a crystal is provided. The method includes steps of providing a crystal growth apparatus according to the above, feeding a primary material into the first crucible of the crystal growth apparatus, heating the first crucible for forming a melting zone and having a melt therein, immersing the second crucible into the melting zone, seeding a crystal seed into the second crucible and controlling a relative movement between the first crucible and the crystal seed, so that a crystal is formed and grown thereby in the crystal growth zone.

Preferably, the melt is obtained from heating and melting the primary material.

Preferably, the crystal growth apparatus further includes a thermal shield for providing a thermal insulation zone for the crystal growth zone.

Preferably, the second crucible further has at least a hole on a wall thereof.

Preferably, the crystal growth apparatus further includes a second heater configured around the crystal growth zone.

Preferably, the primary material is a solid.

Preferably, the second crucible further has at least a hole on a wall thereof.

Preferably, the crystal growth apparatus further has a second heater configured around the crystal growth zone.

Preferably, the relative movement is resulting from pushing the first crucible and pulling the crystal seed.

Preferably, the first crucible is pushed at a velocity associated with a mass equilibrium between the primary crystal and the crystal.

Preferably, the melt and the primary material are prepared independently.

Preferably, the melt and the primary material are prepared by one selected form a group consisting of a monodirection solidifying, a batch solidifying and a sintering.

Preferably, the method further includes a step of controlling a diameter of the crystal while the crystal is formed and grown by one selected from a group consisting of controlling a power of the first heater, controlling a velocity of pulling the crystal seed, and controlling a speed of feeding the primary material.

Preferably the crystal includes one selected from a group consisting of a semiconductor, an oxide, a ceramic, a photo-crystals and an organic material.

In accordance with a third aspect of the present invention, a method for forming a crystal is provided. The method includes steps of providing a crystal growth apparatus according to the above, preparing a composition of a primary material, feeding the primary material into the first crucible of the crystal growth apparatus, heating the first crucible for forming a melting zone and having a melt therein, preparing a composition of the melt, immersing the second crucible into the melting zone and seeding a crystal seed into the second crucible for forming and growing a crystal.

Preferably, the melt is obtained from heating and melting the primary material.

The foregoing and other features and advantages of the present invention will be more clearly understood through the following descriptions with reference to the drawings, wherein:

### BRIEF DESCRIPTION OF THE DRAWINGS

FIG. 1 is a diagram illustrating the arrangement of the conventional crystal growth apparatus according to the prior art;

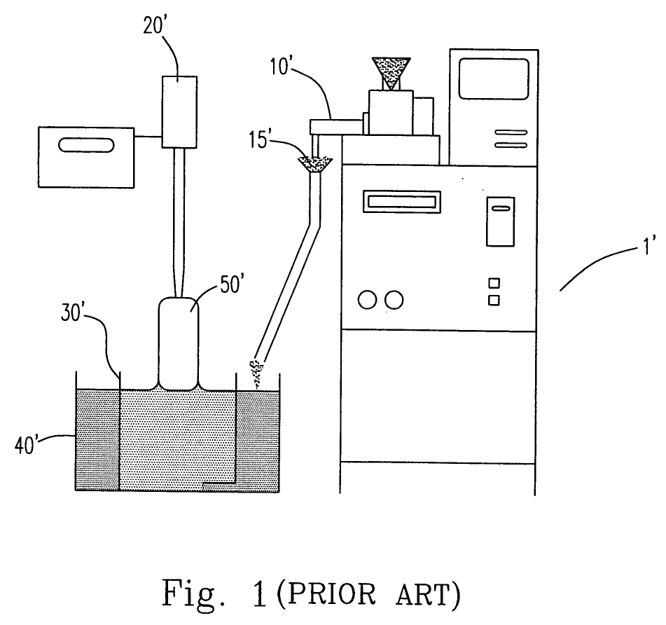

FIG. 2 is a cross sectional view of the arrangement of the crystal growth apparatus according to the preferred embodiment of the present invention;

FIG. 3 is a diagram illustrating the second crucible in the crystal growth apparatus according to the preferred embodiment of the present invention;

FIG. 4 is a flow chart illustrating the method for growing the crystal according to the preferred embodiment of the present invention; and

FIG. 5 is a diagram showing the optical property of the crystal grown by the crystal growth apparatus according to the preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

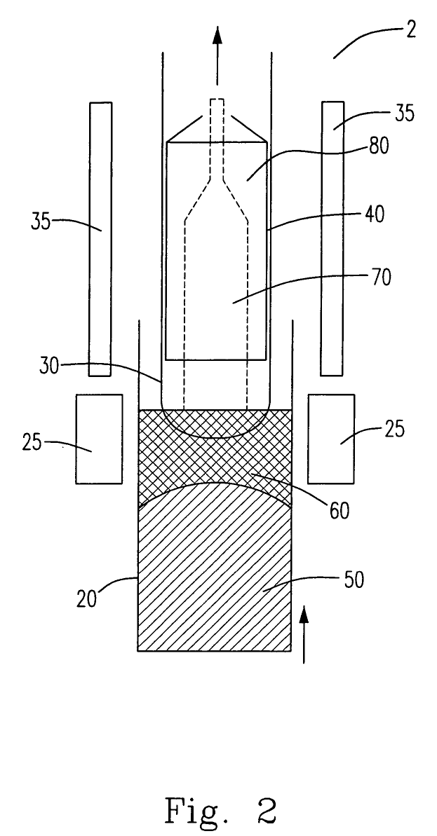

Please refer to FIG. 2, which illustrates the crystal growth apparatus according to a preferred embodiment of the present invention. The crystal growth apparatus 2 has a first crucible 20, a first heater 25, a second crucible 30, a second heater 35, a thermal shield 40 and a thermal isolated cover (not shown). The solid 50 is fed into the first crucible 20 for being the primary material of the crystal. The first crucible 20 is heated by the first heater 25, and a part of the solid 50 therein is heated and melted, so that the melting zone 60 is able to be formed in the first crucible 20. In the crystal growth process, the second crucible 30 is immersed in the melting zone 60. After being seeded into the melting zone 60, the crystal seed (not shown) is gradually pulled off the melting zone 60 by a pulling system (not shown), and the crystal 70 is hence grown in a crystal growth zone 80.

In the crystal growth apparatus 2, the second heater 35 and the thermal shield 40 play important roles in providing a thermal isolation zone for the crystal growth zone 80 to mitigate the temperature change while the crystal 70 is pulled off the second crucible 30. Hence the crack of the crystal 70 generated from a sharp gradient variation of temperature is able to be prevented thereby.

In the crystal growth process, since the crystal 70 is pulled and the first crucible 20 is kept on being pushed by a pushing system (not shown), the melting zone 60 is hence kept on following the pulled crystal 70. Therefore, the length of the grown crystal is able to be improved and a long crystal is obtained therefrom.

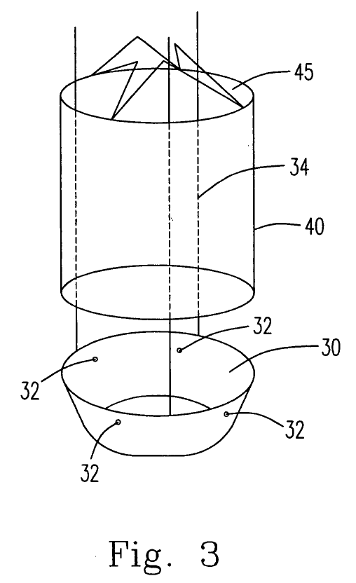

Please refer to FIG. 3, which illustrates the structure of the second crucible in the crystal growth apparatus according to the preferred embodiment of the present invention. The second crucible 30 has holes 32 on the wall thereof, and hence the melt is able to flow into the second crucible 30 thereby when the second crucible 30 is immersed into the melting zone (not shown). The holes 32 are well designed on the side of the second crucible 30 and have a size, which is smaller than that of the air bubbles. Accordingly, the holes 32 only allow the melt flowing into the second crucible 30 therethrough, but stop the air bubbles entering. Therefore, a crystal having no air bubbles therein could be grown and formed thereby. The second crucible 30 is configured in the present crystal growth apparatus by fixed supports 34. Moreover, the second crucible 30 could also be configured in a conventional crystal growth apparatus, and hence is operated as a collocated fixed inner crucible therein. Furthermore, the thermal shield 40 and the thermal isolated cover 45 are configured on the fixed supports 34 for providing the thermal isolation to prevent the thermal stress of the crystal resulting form the thermal gradient.

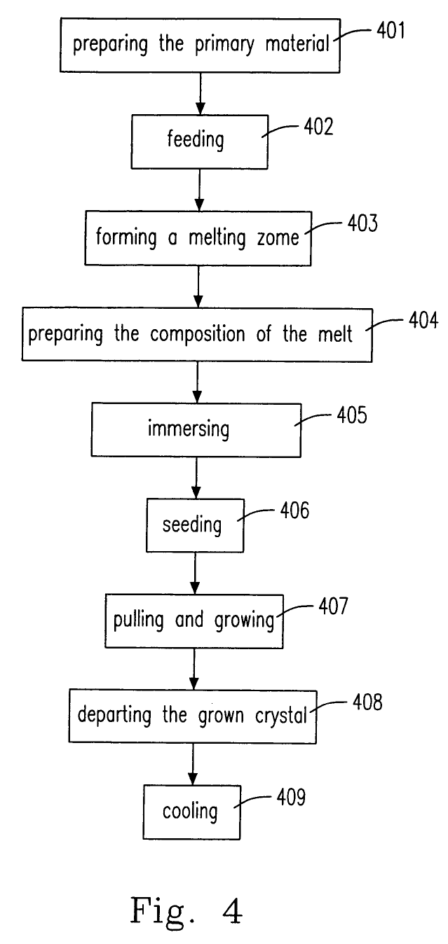

Please refer to FIG. 4, which is a flow chart illustrating the method for growing the crystal adopted for the crystal growth apparatus according to the present invention. The method includes the steps described as follows. First, the composition of the primary material for the crystal is prepared in step 401. Second, in step 402, the primary material is fed into the first crucible of the crystal growth apparatus. Then, in step 403, the first crucible is heated to form a melting zone having a melt therein in the first crucible. The composition of the melt is prepared in step 404. In step 405, the first crucible is pushed forward to make the second crucible be immersed in the melting zone therein. Next, the crystal seed is seeded into the melting zone while the temperature therein and the melt composition are stable, i.e. step 406. The crystal seed is gradually pulled off the melting zone in step 407, and the first crucible is slowly pushed by the pushing system to follow the pulled crystal seed at the same time. Hence the crystal is gradually grown and attached onto the crystal seed due to the relative movement between the crystal seed and the first crucible and the decreased temperature. The grown crystal having a needed length is departed and the first crucible is lowed off the second crucible in step 408. Finally, in step 409, the grown crystal is cooled and a crystal bar is formed accordingly.

In the crystal growth apparatus and the method for growing the crystal provided in the present invention, the composition of the primary material could be prepared and fed into the first crucible as a solid, wherein the composition is adjustable and depends on the demand. In addition, the primary material and the melt may be prepared through repeatedly sintering, monodirection solidifying or batch solidifying. Additives, such as appropriate flux and doping, are separately prepared and then added into the melt based on the phase diagram indications. For example, the composition of melt could be one with a Li/Nb ratio of 59/41 if a stoichiometric LN crystal is to be grown. Additionally, other kinds of fluxes and dopings are able to be added into the melt if necessary.

In the crystal growing process, the first crucible is pushed forward at a pushing velocity U_{f}, which is calculated from the equation according to the mass equilibrium between the grown crystal and the solid primary material, i.e. the equation of ρ_{C}U_{C}A_{C}=ρ_{f}U_{f}A_{f}, wherein ρ_{C}, U_{C} and A_{C} are respectively the density, the pulling velocity and the cross-sectional area of the grown crystal, ρ_{f} is the density of the solid primary material, and U_{f} and A_{f} are respectively the pushing velocity and the inner cross-sectional area of the first crucible.

Moreover, there are holes designed on the wall of the appended second crucible. The holes only allow the melt in the melting zone to flow into the second crucible due to the designed size and location thereof. That is to say, the holes are smaller than the size of the air bubbles and are configured on the side of the second crucible to prevent the air bubbles, which are produced when the primary material is melted, inset the crystal while the crystal is growing. Therefore, the present invention successfully provides an apparatus and a method for growing a crystal having no air bubbles therein. The grown crystal would not easily be cracked and hence has a good uniformity and an excellent quality.

In addition, the thermal shield and the thermal isolated cover configured in the crystal growth apparatus of the present invention are able to replace the second heater, which is configured around the second crucible. The thermal gradient is reduced when the grown crystal is pulled off the melting zone due to a thermal isolation provided thereby. As a result, the crack of the grown crystal would be reduced thereby.

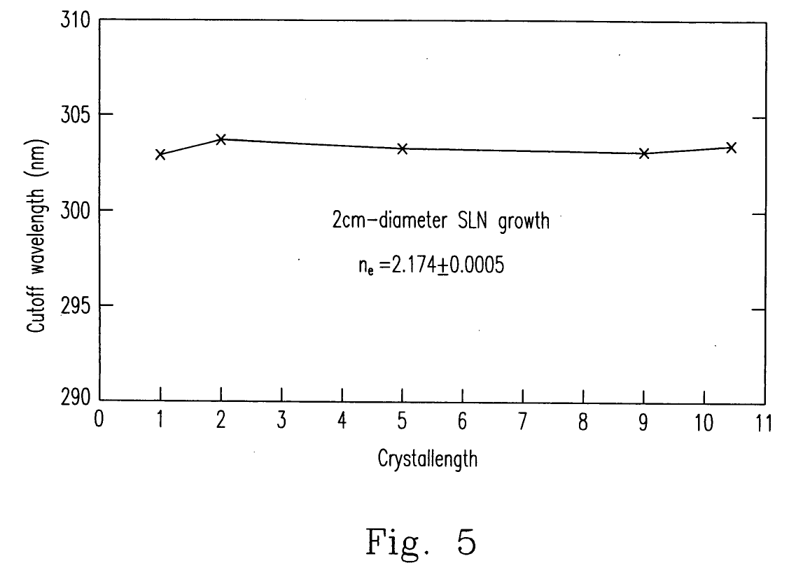

Please refer to FIG. 5, which is a diagram illustrating the optical property of the photo-crystal grown from the apparatus of the present invention. The photo-crystal grown from the present apparatus has a better optical property than that of the crystals grown from the conventional crystal growth apparatus. For example, the cutoff wavelength and the irregular refractive index (nₑ) of the stoichiometric LN crystal having the doping MgO therein while grown from the apparatus of the present invention are so stable and independent of the length variation of the grown crystal. In other words, the LN single crystal grown from the apparatus of the present invention is able to exhibit a uniform and excellent optical property.

Furthermore, the crystal growth apparatus and the method of the present invention may be applied for growing the semiconductor, the oxide, the ceramic and the organic material crystals.

Besides, based on the analysis, the concentration variation of the doping MgO could be easily controlled in a range of 5% through the growth method of the present invention. It is helpful to improve the quality of the grown crystal, which is indeed another technical advantage of the present invention.

Based on the above, the present invention provides a simplified apparatus and a method for growing a long single crystal with great uniformity. The arrangement of the provided crystal growth apparatus is simplified, and the designed second crucible could be further configured in the conventional crystal growth apparatus, which is existed and used in the industry. The energy consumption of the crystal growth apparatus of the present invention is reduced due to a scheme of zone-melting. Furthermore, both of the diameter and the length of the grown crystals are well controlled, which improves the uniformities of the compositions in axial and in radial. Therefore, the present invention not only has a novelty and a progressiveness, but also has an industry utility.

While the invention has been described in terms of what is presently considered to be the most practical and preferred embodiment, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A crystal growth apparatus, comprising:
a first crucible;
a first heater configured around said first crucible;
a second crucible configured inside said first crucible;
a pulling system for pulling a crystal, so as to grow said crystal in a crystal growth zone; and
a moving system for forming a relative movement between said first crucible and said second crucible.

2. The crystal growth apparatus according to claim 1, further comprising a thermal shield for providing a thermal insulation zone for said crystal growth zone.

3. The crystal growth apparatus according to claim 2, wherein said second crucible further has at least a hole on a wall thereof.

4. The crystal growth apparatus according to claim 3, further comprising a second heater configured around said crystal growth zone.

5. The crystal growth apparatus according to claim 1, wherein said second crucible is configured inside said first crucible by a fixed support.

6. The crystal growth apparatus according to claim 1, wherein said second crucible further has at least a hole on a wall thereof.

7. The crystal growth apparatus according to claim 6, further comprising a second heater configured around said crystal growth zone.

8. The crystal growth apparatus according to claim 1, further comprising a second heater configured around said crystal growth zone.

9. A method for forming a crystal, comprising steps of:
providing a crystal growth apparatus according to claim 1;
feeding a primary material into said first crucible of said crystal growth apparatus;
heating said first crucible for forming a melting zone and having a melt therein, wherein said melt is obtained from heating and melting said primary material;
immersing said second crucible into said melting zone;
seeding a crystal seed into said second crucible; and
controlling a relative movement between said first crucible and said crystal seed, so that a crystal is formed and grown thereby in said crystal growth zone.

10. The method according to claim 9, wherein said crystal growth apparatus further comprises a thermal shield for providing a thermal insulation zone for said crystal growth zone.

11. The method according to claim 10, wherein said second crucible further has at least a hole on a wall thereof.

12. The method according to claim 11, wherein said crystal growth apparatus further comprises a second heater configured around said crystal growth zone.

13. The method according to claim 9, wherein said primary material is a solid.

14. The method according to claim 9, wherein said second crucible further has at least a hole on a wall thereof.

15. The method according to claim 14, wherein said crystal growth apparatus further has a second heater configured around said crystal growth zone.

16. The method according to claim 9, wherein said crystal growth apparatus further has a second heater configured around said crystal growth zone.

17. The method according to claim 9, wherein said relative movement is resulting from pushing said first crucible and pulling said crystal seed.

18. The method according to claim 17, wherein said first crucible is pushed at a velocity associated with a mass equilibrium between said primary crystal and said crystal.

19. The method according to claim 9, wherein said melt and said primary material are prepared independently.

20. The method according to claim 9, wherein said melt and said primary material are prepared by one selected form a group consisting of a monodirection solidifying, a batch solidifying and a sintering.

21. The method according to claim 9, further comprising a step of controlling a diameter of said crystal while said crystal is formed and grown by one selected from a group consisting of controlling a power of said first heater, controlling a velocity of pulling said crystal seed, and controlling a speed of feeding said primary material.

22. The method according to claim 9, wherein said crystal comprises one selected from a group consisting of a semiconductor, an oxide, a ceramic, a photo-crystal and an organic material.

23. A method for forming a crystal, comprising steps of:
providing a crystal growth apparatus according to claim 1;
preparing a composition of a primary material;
feeding said primary material into said first crucible of said crystal growth apparatus;
heating said first crucible for forming a melting zone and having a melt therein, wherein said melt is obtained from heating and melting said primary material;
preparing a composition of said melt;
immersing said second crucible into said melting zone; and
seeding a crystal seed into said second crucible for forming and growing a crystal.
